(19) United States
(12) Patent Application Publication
(10) Pub. No.: US 2025/0226344 A1
(43) Pub. Date: Jul. 10, 2025

(54) CORE BALL AND SEMICONDUCTOR PACKAGE INCLUDING THE SAME

(71) Applicant: MK ELECTRON CO., LTD., Yongin-si (KR)

(72) Inventors: Jae Yeol SON, Yongin-si (KR); Ji Won PARK, Anyang-si (KR); Byung Woo KIM, Yongin-si (KR); Young Woo LEE, Yongin-si (KR); Hui Joong KIM, Yongin-si (KR); Seul Gi LEE, Yongin-si (KR); Jong Min WON, Yongin-si (KR)

(73) Assignee: MK ELECTRON CO., LTD., Yongin-si, GG (KR)

(21) Appl. No.: 19/012,365

(22) Filed: Jan. 7, 2025

(30) Foreign Application Priority Data
Jan. 10, 2024 (KR) 10-2024-0004270

(51) Int. Cl. H01L 23/00

(52) U.S. Cl. CPC H01L 24/13; H01L 24/16; H01L 24/11; H01L 2224/11462; H01L 2224/11464; H01L 2224/13005; H01L 2224/13014; H01L 2224/13083; H01L 2224/13109; H01L 2224/13111; H01L 2224/13113; H01L 2224/1312; H01L 2224/13124; H01L 2224/13147; H01L 2224/13155; H01L 2224/13611; H01L 2224/13639; H01L 2224/13647; H01L 2224/16227; H01L 2924/3656

(57) ABSTRACT

A core ball includes a core that is metal or plastic, a first metal layer formed on a surface of the core, a second metal layer formed on the first metal layer and including a tin (Sn)—bismuth (Bi) binary alloy, and a third metal layer formed on the second metal layer and including a single metal of tin (Sn), wherein a melting point of an alloy of a material forming the second metal layer and a material forming the third metal layer is 150° C. or less.

### CROSS-REFERENCE TO RELATED APPLICATION

This application claims the benefit of Korean Patent Application No. 10-2024-0004270, filed on Jan. 10, 2024, in the Korean Intellectual Property Office, the disclosure of which is incorporated herein in its entirety by reference.

### BACKGROUND

### 1. Field

The disclosure relates to a core ball and a semiconductor package including the core ball, and more particularly, to a core ball having a low-melting point alloy plated on a core, and a semiconductor package including the core ball.

### 2. Description of the Related Art

Tin (Sn)-lead (Pb)-based alloy products have been mainly used as solders for electronic products. In particular, lead has been a component that determines the wettability, strength, and mechanical properties of an alloy. By including lead, the melting point may be lowered to 183° C., thus preventing thermal damage that occurs during soldering in semiconductor processes. As regulations regarding environmental issues due to lead become stricter, ternary lead-free solder alloys of tin (Sn)—silver (Ag)—copper (Cu) have been proposed. In order to achieve high-density mounting of semiconductor packages, plating balls have been used, in which nickel (Ni) is plated on a metallic or non-metallic core, and then a binary plating layer such as tin (Sn)—silver (Ag) or a ternary plating layer such as tin (Sn)—silver (Ag)—copper (Cu) is formed thereon to transmit electrical signals of the semiconductor package. Various studies are being conducted on this technique.

### SUMMARY

Provided is a high-quality core ball with a low melting point.

Provided is a semiconductor package with excellent properties of both electrical and mechanical properties because, when a semiconductor package is manufactured using a high-quality core ball with a low melting point, warpage in semiconductor packages is resolved through a low-temperature process so that high-quality results may be obtained.

The technical objectives to be achieved by the disclosure are not limited to the above-described objectives, and other technical objectives that are not mentioned herein would be clearly understood by a person skilled in the art from the description of the disclosure.

According to an aspect of the disclosure, a core ball includes a core that is metal or plastic, a first metal layer formed on a surface of the core, a second metal layer formed on the first metal layer and including a tin (Sn)—bismuth (Bi) binary alloy, and a third metal layer formed on the second metal layer and including a single metal of tin (Sn), wherein a melting point of an alloy of a material forming the second metal layer and a material forming the third metal layer is 150° C. or less.

In an embodiment, the diameter of the core may be 50 μm to 800 μm, the thickness of the first metal layer may be 0.1 μm to 4 μm, and the first metal layer may further includes nickel (Ni).

In an embodiment, the diameter of the core may be 50 μm to 800 μm, and the first metal layer may be omitted.

In an embodiment, Bi may be uniformly distributed in the second metal layer by a stabilizer for Bi, and Bi may not be detected from the third metal layer.

According to another aspect of the disclosure, a core ball includes a core that is metal or plastic, a first metal layer formed on a surface of the core, a second metal layer formed on the first metal layer and including any one alloy selected from among tin (Sn)—bismuth (Bi), tin (Sn)—indium (In), bismuth (Bi)—indium (In), tin (Sn)—bismuth (Bi)—silver (Ag), and tin (Sn)—bismuth (Bi)—antimony (Sb), and a third metal layer formed on the second metal layer and including an alloy of tin (Sn) and at least one selected from silver (Ag) and copper (Cu), wherein a melting point of an alloy of a material forming the second metal layer and a material forming the third metal layer is 150° C. or less, and the third metal layer may include 80 wt % or more of tin (Sn).

In an embodiment, the core ball may include a Bi content of 30 wt % to 70 wt %, an Ag content of 0.01 wt % to 2.0 wt %, a Cu content of 0.01 wt % to 0.8 wt %, and the balance of Sn and other inevitable impurities.

In an embodiment, the melting point of an alloy of a material forming the second metal layer and a material forming the third metal layer may be 138° C.

According to another aspect of the disclosure, a semiconductor package includes a substrate on which a plurality of first terminals may be formed, a semiconductor device mounted on the substrate and including a plurality of second terminals corresponding to the plurality of first terminals, and a plurality of solder bumps connecting the plurality of first terminals to the plurality of second terminals, which correspond to each other, wherein the plurality of solder bumps each include any one of the core balls described above.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a core ball according to an embodiment;

FIG. 2 is a microscopic image showing a part of the core ball of FIG. 1;

FIGS. 3A and 3B are microscopic images showing a difference depending on the presence of a third plating layer in the core ball of FIG. 1;

FIG. 4 is a graph showing a change in characteristics according to a difference in a constituent material in the core ball of FIG. 1;

FIGS. 5A, 5B, 5C, and 5D are microscopic images showing analysis results according to some embodiments;

FIG. 6 is a graph showing analysis results according to some embodiments;

FIGS. 7A and 7B and FIGS. 8A, 8B, and 8C are X-ray images of void distribution after bonding core balls to a semiconductor device;

FIGS. 9A, 9B, and 9C are microscopic images showing analysis results according to some embodiments; and

FIG. 10 illustrates a semiconductor package including a core ball according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure are described in detail with reference to the accompanying drawings. However, this disclosure may, however, be embodied in many different forms and should not be construed as limited to the embodiments set forth herein.

Furthermore, various components and regions in the drawings are schematically illustrated. Accordingly, the disclosure is not limited by the relative size or distance drawn in the accompanying drawings. Furthermore, in embodiments of the disclosure, wt % (weight %) is the weight percentage that a component makes up of the total alloy weight. Furthermore, in embodiments of the disclosure, complete removal means absence to a degree that is difficult to detect even with a high-performance component analyzer.

Terms such as “first” and “second” are used herein merely to describe a variety of constituent elements, but the constituent elements are not limited by the terms. Such terms are used only for the purpose of distinguishing one constituent element from another constituent element. For example, without departing from the right scope of the disclosure, a first constituent element may be referred to as a second constituent element, and vice versa.

Unless defined otherwise, all terms used herein including technical or scientific terms have the same meanings as those generally understood by those of ordinary skill in the art to which the disclosure may pertain. The terms as those defined in generally used dictionaries are construed to have meanings matching that in the context of related technology and, unless clearly defined otherwise, are not construed to be ideally or excessively formal.

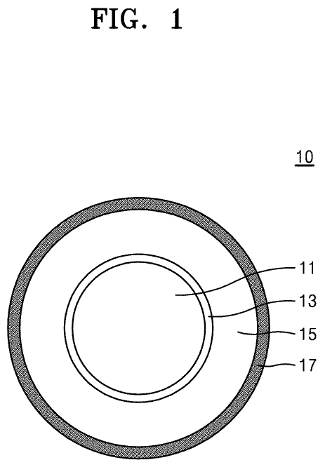

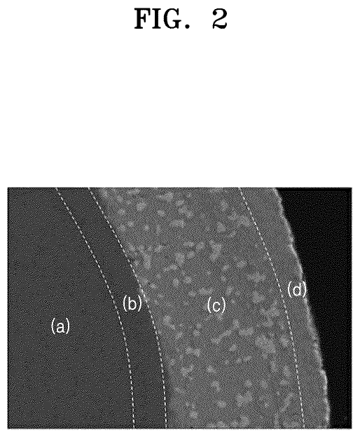

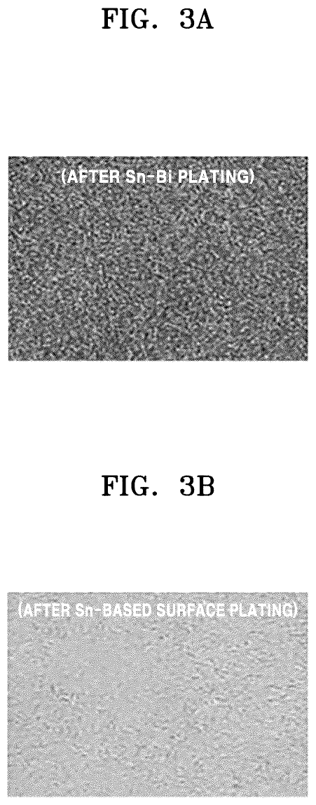

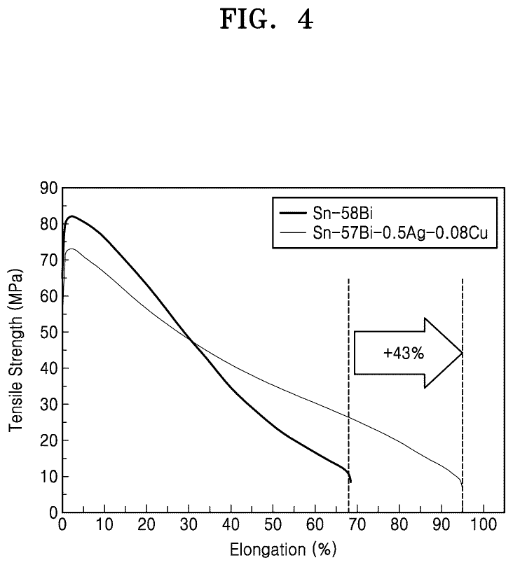

FIG. 1 is a cross-sectional view of a core ball 10 according to an embodiment. FIG. 2 is a microscopic image showing a part of the core ball 10 of FIG. 1. FIGS. 3A and 3B are microscopic images showing a difference depending on the presence of a third plating layer in the core ball 10 of FIG. 1. FIG. 4 is a graph showing a change in characteristics according to a difference in a constituent material in the core ball 10 of FIG. 1.

Referring to FIGS. 1 and 2 together, the core ball 10 may include a core 11 that is metal or plastic, a first metal layer 13 formed on a surface of the core 11, a second metal layer 15 formed on the first metal layer 13 and including a tin (Sn)—bismuth (Bi) binary alloy, and a third metal layer 17 formed on the second metal layer 15 and including a single metal of Sn.

The core 11 may be formed of a general metal material, an organic material, an organic/organic composite material, or an organic/inorganic composite material.

The core 11 with an organic material may be, for example, the core 11 with a plastic material, and the core 11 with a plastic material may include a plastic core 11 including a thermosetting resin, such as an epoxy type, a melamine-formaldehyde type, a benzoguanamine-formaldehyde type, divinylbenzene, divinyl ether, polydiacrylate, or alkylene bisacrylamide; a plastic core 11 including a thermoplastic resin, such as polyvinyl chloride, polyethylene, polystyrene, nylon, or polyacetal; and an elastic core 11, such as natural rubber or synthetic rubber. Furthermore, the core 11 with a plastic material may include a plastic core 11 formed of resin combining thermosetting resin and thermoplastic resin.

The core 11 with a plastic material may be formed by using a polymer synthesis method. In some embodiments, through a synthesis method, such as suspension, emulsification, a dispersion polymerization method, etc. the core 11 with a plastic material may be formed to have a diameter of 50 μm to 800 μm. When the diameter of the core 11 is less than 50 μm or greater than 800 μm, it may be difficult to mount the core 11 on a semiconductor package 100 described below.

The core 11 of the above metal material may be configured with, for example, pure copper (Cu), nickel (Ni), aluminum (Al), or an alloy thereof, but the disclosure is not limited thereto.

Although the drawing illustrates that the shape of the core 11 is spherical, the core 11 may have various shapes, such as a cylindrical shape, a square prism shape, a polygonal prism shape, a cone shape, a pyramid shape, etc.

The first metal layer 13 may be provided on the core 11. The first metal layer 13 may be formed on the core 11 directly or via another material layer.

The component of the first metal layer 13 may include a metal, such as gold (Au), silver (Ag), Ni, zinc (Zn), Sn, Al, chromium (Cr), cobalt (Co), antimony (Sb), etc. The metals may be used solely or by using two types or more metals together. The first metal layer 13 may be formed by a method, such as plating, physical vapor deposition (PVD), chemical vapor deposition (CVD), etc. In particular, when the first metal layer 13 is formed by plating, an electrolytic plating method using Ni or an electroless plating method may be used. In other words, the first metal layer 13 may include Ni.

When the first metal layer 13 is formed, a brightener may be used to improve roughness of a surface of the first metal layer 13. In other words, by using the brightener, a smoother surface of the first metal layer 13 may be obtained. The brightener may include, for example, an oxygen-containing organic compound such as a polyether compound; a nitrogen-containing organic compound such as a tertiary amine compound and a quaternary ammonium compound; and/or a sulfur-containing organic compound having a sulfonate group, but the disclosure is not limited thereto. In some embodiments, the thickness of the first metal layer 13 may be 0.1 μm to 4 μm. In some embodiments, the first metal layer 13 may be omitted.

The second metal layer 15 may be formed on the surface of the first metal layer 13. In some embodiments, the second metal layer 15 may include a Sn—Bi binary alloy. In some embodiments, the second metal layer 15 may include any one alloy selected from among Sn—Bi, Sn-indium (In), Bi—In, Sn—Bi—Ag, and Sn—Bi—Sb. In the second metal layer 15, Bi may be uniformly distributed by using a stabilizer of Bi. A detailed description thereof is presented below.

The third metal layer 17 may be formed on the surface of the second metal layer 15. In some embodiments, the third metal layer 17 may be formed of a single metal of Sn. In some embodiments, the third metal layer 17 may be formed of an alloy of Sn and at least one selected from Ag and Cu. In some embodiments, the third metal layer 17 may contain more than 80 wt % of Sn. In other words, in any case, Bi may not be detected from the third metal layer 17.

A Sn-lead (Pb)-based alloy product is mainly used as a solder for electronic products. In particular, Pb has operated as a component to determine wetting, strength, and mechanical properties of an alloy. As Pb is contained, the melting point of the alloy may be reduced to 183° C. so that thermal damage occurring in soldering of a semiconductor process may be prevented. As regulations regarding environmental issues caused by lead become stricter, a ternary lead-free solder alloy of Sn—Ag—Cu has been proposed. For high density mounting of a semiconductor package, a plating ball has been used in which Ni is plated on a metal or non-metallic core member and then a binary plating layer such as Sn—Ag or a ternary plating layer such as Sn—Ag—Cu is formed thereon, for transmission of electrical signals of a semiconductor package.

In the core ball 10 according to an embodiment, the melting point of an alloy of a material forming the second metal layer 15 and a material forming the third metal layer 17 may be 150° C. or less. In particular, in the core ball 10 according to an embodiment, the melting point of an alloy of a material forming the second metal layer 15 and a material forming the third metal layer 17 may be 138° C.

First, the following experiment was performed to check discoloration due to oxidation of Bi. After preparing the core balls 10 of a uniform size (e.g., 180 μm), a washing process was performed in a reducing aqueous solution to remove a natural oxide film formed on an outer surface of each of the core balls 10.

When washing is performed in the reducing aqueous solution, the natural oxide film on the outer surface of each of the core balls 10 is removed, thereby improving the adhesion of a Ni underlying layer formed on the outer surface of each of the core balls 10.

In this experiment, a 10% concentration sulfuric acid (H₂SO₄) aqueous solution was used as the reducing aqueous solution, and in order to prevent damage to the outer surface of the core ball 10, the experiment was conducted for a short period of time in an environment where the temperature of the reducing aqueous solution was 20° C. to 25° C.

Next, to form the first metal layer 13 on the core 11, through an electrolytic plating method using Ni, plating was conducted to a thickness of 1 μm to 3 μm. Next, a solder plating layer of a Sn—Bi binary alloy, which is the second metal layer 15, is formed on the first metal layer 13 by an electrolytic plating method. When forming Ni that forms the first metal layer 13, to verify the effect of improving surface roughness, an experiment was conducted using a brightener. When the brightener was added to a Ni plating solution, the roughness of the outer surface of the core ball 10 was improved, and a smooth outer surface was observed.

Next, the brightener was used to form a smooth plating layer on the solder plating layer, which is a Sn—Bi binary alloy that forms the second metal layer 15, and in order to determine the influence of oxidation on the outer surface of the core ball 10, it was observed that the discoloration occurred when the core ball 10 was exposed to the air after plating.

Referring to FIGS. 3A and 3B, although not bound by a specific theory, it was confirmed that, when the core ball 10 is exposed to the air, a rapid change to a black color occurs due to rapid natural oxidation of Bi. Unlike the above, when the outer surface of the core ball 10 is plated with a Sn based material that forms the third metal layer 17, an effect that the rapid oxidation phenomenon due to Bi is improved was confirmed.

In this state, in order to form a Sn—Bi binary alloy that forms the second metal layer 15 on Ni that forms the first metal layer 13, a Sn and Bi ion-concentrated electrolyte of the sulfonic acid series was used, and a single Sn or Sn, Ag, and Cu ion electrolyte was used as the third metal layer 17. In all embodiments described above, it was observed that the melting point of the plated composition is 150° C. or less, in detail, 138° C., without change. A detailed description thereof is described below.

In general, it has been known that it is a demerit of the Sn—Bi binary alloy (e.g., a Sn-58Bi alloy) that is a low-melting-point solder that creep properties are relatively low due to brittle properties of Bi. Accordingly, in order to improve the creep properties, Ag or Cu may be added in small amounts to the Sn—Bi binary alloy. The effect according thereto is described below.

Referring to FIG. 4, as for the core ball 10 according to an embodiment, it is actually difficult to directly confirm the mechanical properties of a surface plating layer depending on the structural role when a product is used. Accordingly, the properties of a solder alloy is evaluated as alternative properties, and differences between the properties of a Sn-58Bi alloy and the properties of a Sn-57Bi-0.5Ag-0.8Cu alloy are compared and shown in the graph.

It was observed that the composition of the Sn-40-60Bi-0.5Ag-0.08Cu alloy formed through the plating of Ag and Cu in the third metal layer 17 of the core ball 10 increased an elongation by more than 40%, compared to the Sn-58Bi alloy.

In other words, it may be seen that, due to the role of the third metal layer 17, the overall physical properties of the core ball 10 are improved, the oxidation of the outer surface of the core ball 10 is suppressed, and it is possible to manufacture a high-quality, low-melting-point solder alloy core ball 10 exhibiting void-free level bonding characteristics.

To this end, the core ball 10 according to an embodiment may be configured to include a Bi content of 30 wt % to 70 wt %, an Ag content of 0.01 wt % to 2.0 wt %, a Cu content of 0.01 wt % to 0.8 wt %, and the balance of Sn and other inevitable impurities, but the disclosure is not limited thereto.

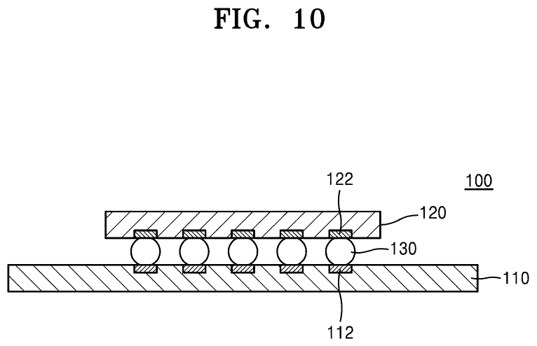

Accordingly, according to an embodiment, when the semiconductor package 100 (see FIG. 10) is manufactured by using a high-quality core ball with a low melting point, warpage of the semiconductor package 100 is addressed by a low temperature process so that a high-quality result may be obtained. Thus, there is an effect of providing the semiconductor package 100 (see FIG. 10) with excellent properties of both electrical and mechanical properties.

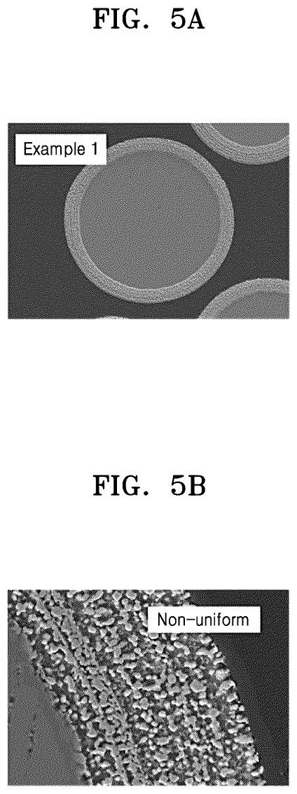

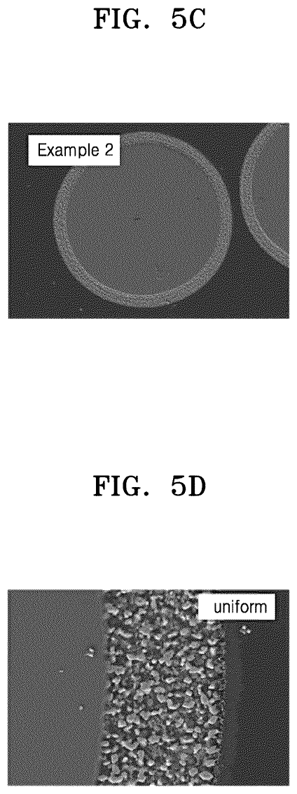

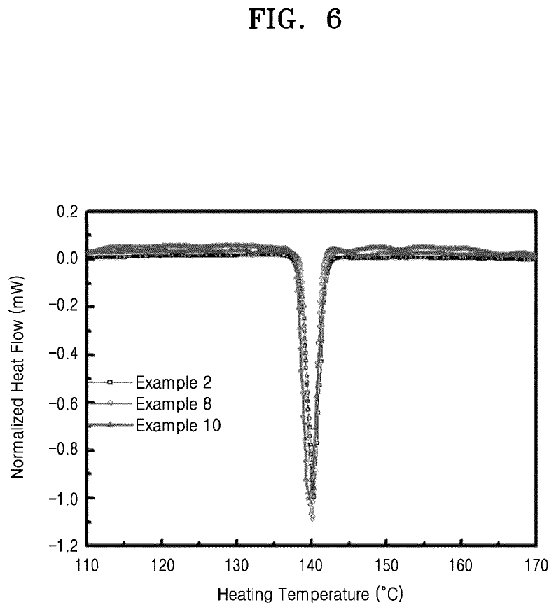

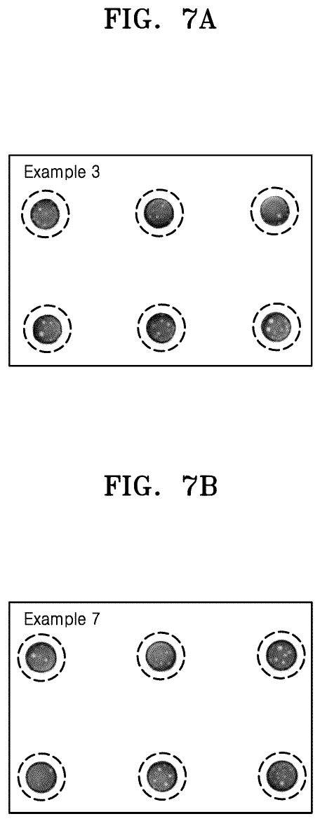

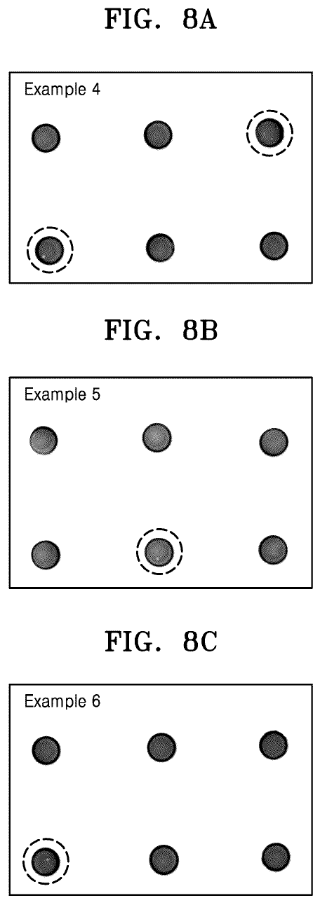

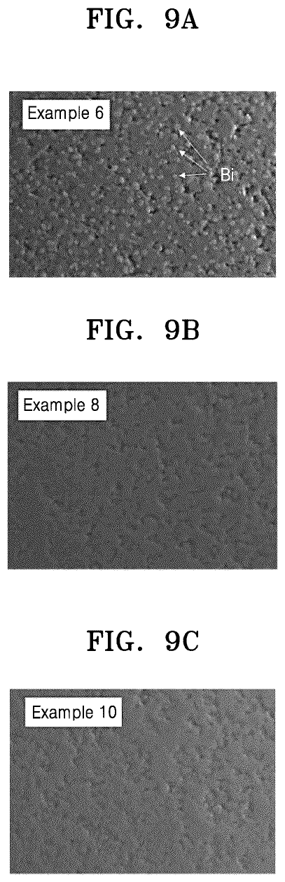

FIGS. 5A, 5B, 50, and 5D are microscopic images showing analysis results according to some embodiments. FIG. 6 is a graph showing analysis results according to some embodiments. FIGS. 7A and 7B and FIGS. 8A, 8B, and 8C are X-ray images of void distribution after bonding core balls to a semiconductor device. FIGS. 9A, 9B, and 9C are microscopic images showing analysis results according to some embodiments.

In order to evaluate the core ball 10 (see FIG. 1) according to the disclosure, experiments such as Table 1 below are repeatedly performed with various conditions. Each embodiment is independently performed, and any one embodiment does not affect another embodiment.

In Table 1 below, a stabilizer refers to a stabilizer for Bi, and an additive refers to a crystallization refining additive or a brightener. Furthermore, the presence of a void refers to a void appearing after the core ball is bonded to a semiconductor package.

TABLE 1

| | | | | | | | First | Second | Third | | | Plating | Pres- |
|---|---|---|---|---|---|---|---|---|---|---|---|---|---|
| | | | | | Stabi- | | Metal | Metal | Metal | | Melting | Effi- | ence of |
| | Sn—Bi | Sn | Ag | Cu | lizer | Additive | Layer | Layer | Layer | Plating Composition | Point | ciency | Void |
| Example | ◯ | X | X | X | 0 ml/L | X | 1.5~3 μm | ◯ | X | Sn-50~65Bi | 138° C. | 75% | Large |
| 1 | | | | | | | | | | | | | Amount |
| Example | ◯ | X | X | X | 3 ml/L | X | 1.5~3 μm | ◯ | X | Sn-50~65Bi | 138° C. | 75% | Small |
| 2 | | | | | | | | | | | | | Amount |
| Example | ◯ | X | X | X | 5 ml/L | X | 1.5~3 μm | ◯ | X | Sn-50~65Bi | 138° C. | 65% | Large |
| 3 | | | | | | | | | | | | | Amount |
| Example | ◯ | X | X | X | 3 ml/L | 0.00 ml/L | 1.5~3 μm | ◯ | X | Sn-50~65Bi | 138° C. | 75% | Small |
| 4 | | | | | | | | | | | | | Amount |
| Example | ◯ | X | X | X | 3 ml/L | 0.03 ml/L | 1.5~3 μm | ◯ | X | Sn-50~65Bi | 138° C. | 77% | Small |
| 5 | | | | | | | | | | | | | Amount |
| Example | ◯ | X | X | X | 3 ml/L | 0.05 ml/L | 1.5~3 μm | ◯ | X | Sn-50~65Bi | 138° C. | 80% | Small |
| 6 | | | | | | | | | | | | | Amount |
| Example | ◯ | X | X | X | 3 ml/L | 0.15 ml/L | 1.5~3 μm | ◯ | X | Sn-50~65Bi | 138° C. | 83% | Large |
| 7 | | | | | | | | | | | | | Amount |
| Example | ◯ | ◯ | X | X | 3 ml/L | 0.05 ml/L | 1.5~3 μm | ◯ | ◯ | Sn-50~65Bi | 138° C. | 80% | Void- |
| 8 | | | | | | | | | | | | | Free |
| Example | ◯ | ◯ | ◯ | ◯ | 3 ml/L | 0.05 ml/L | 1.5~3 μm | ◯ | ◯ | Sn-45~60Bi—0.3Ag—0.05Cu | 138° C. | 80% | Void- |
| 9 | | | | | | | | | | | | | Free |
| Example | ◯ | ◯ | ◯ | ◯ | 3 ml/L | 0.05 ml/L | 1.5~3 μm | ◯ | ◯ | Sn-45~60Bi—0.5Ag—0.09Cu | 138° C. | 80% | Void- |
| 10 | | | | | | | | | | | | | Free |
| Example | ◯ | ◯ | ◯ | ◯ | 3 ml/L | 0.05 ml/L | 1.5~3 μm | ◯ | ◯ | Sn-45~60Bi—1.0Ag—0.20Cu | 138° C. | 80% | Void- |
| 11 | | | | | | | | | | | | | Free |
| Example | ◯ | ◯ | X | ◯ | 3 ml/L | 0.05 ml/L | 1.5~3 μm | ◯ | ◯ | Sn-45~60Bi—0.5Cu | 138° C. | 80% | Void- |
| 12 | | | | | | | | | | | | | Free |
| Example | ◯ | ◯ | X | X | 3 ml/L | 0.05 ml/L | 1.5~3 μm | ◯ | ◯ | Sn-45~60Bi—1.0Ag | 138° C. | 80% | Void- |
| 13 | | | | | | | | | | | | | Free |
| Example | ◯ | ◯ | X | X | 3 ml/L | 0.05 ml/L | X | ◯ | ◯ | Sn-50~65Bi | 138° C. | 80% | Void- |
| 14 | | | | | | | | | | | | | Free |
| Example | ◯ | ◯ | X | X | 3 ml/L | 0.05 ml/L | 0.1~0.5 μm | ◯ | ◯ | Sn-50~65Bi | 138° C. | 80% | Void- |
| 15 | | | | | | | | | | | | | Free |
| Example | ◯ | ◯ | X | X | 3 ml/L | 0.05 ml/L | 2.5~4 μm | ◯ | ◯ | Sn-50~65Bi | 138° C. | 80% | Void- |
| 16 | | | | | | | | | | | | | Free |

Referring to FIGS. 5A, 5B, 50, and 5D and Table 1 together, the results of experiments on appropriate usages of a stabilizer for Bi in the core ball are presented.

When no stabilizer is used as in Example 1, an oxidation phenomenon relatively rapidly occurs on a surface in Example 1. A clumping phenomenon of Bi was observed on the surface in Example 1 in a relatively large amount.

Alternatively, when an amount of a stabilizer is excessive as in Example 3, it was observed that the efficiency of plating is reduced and thus a plating time increases relatively. Accordingly, in particular, it was confirmed that, as in Example 2, the most appropriate dose of stabilizer is 3 ml/L.

In particular, it was observed that, due to the role of stabilizer, uniformity of an alloy in a metal layer is an effect of Example 2. For example, in Example 1, since no stabilizer was added, a Bi accumulation phenomenon in the form of a band like a tree ring was observed due to a non-uniform alloy distribution. Unlike the above, it may be confirmed that, as in Example 2, when a stabilizer of 3 ml/L is added, uniform alloy plating is formed.

Examples 4 to 7 in Table 1 are evaluations of additives for forming crystallization refining, and it was observed that the plating efficiency increased as the content of the additive increased. Thus, it was determined that there was a positive effect.

However, due to the general characteristics of organic brighteners, when the content of additives increases significantly, organic brightener components may evaporate in a bonding process through reflow. Accordingly, a problem was identified where a void was formed within the core ball.

Thus, it was confirmed that the conditions for a desirable additive were such that, as in Example 6, where 0.05 ml/L of an additive was added, only a relatively small amount of voids was formed due to uniform alloy plating.

Referring to FIG. 6 and Table 1 together, the experimental results that may determine the melting point of the alloy in the core ball are shown. In the graph, the X axis denotes a heating temperature in examples, and the Y axis denotes a normalized heat flow according to the heating temperature. By using this, it may be determined that, in Examples 2, 8, and 10, the melting point of an alloy according to the composition of the core ball is 150° C. or less, specifically 138° C.

Referring to FIGS. 7A and 7B and Table 1 together, a degree of formation of a void during bonding of the core ball to the semiconductor package. It may be confirmed that, in Examples 3 and 7, a relatively large amount of voids is formed inside the core ball.

Referring to FIGS. 8A, 8B, and 8C and Table 1 together, a degree of formation of a void bonding the core ball to the semiconductor package is shown. It may be confirmed that, in Examples 4 to 6, a relatively small amount of voids is formed inside the core ball.

In other words, although not bound by a specific theory, it was confirmed that, after an appropriate amount of additive is added, crystal grains of Sn are very densely plated on the outer surface of the core ball, and the density of a low temperature solder alloy plating layer is relatively increased, and thus is represented as a phenomenon that a void is restricted.

Examples 14 to 16 in Table 1 show results according to the presence and a thickness of the first metal layer. In other words, the thickness of the first metal layer may be 0.1 μm to 4 μm, in particular 1.5 μm to 3 μm. In some cases, the first metal layer may be omitted. In this case, when other conditions are satisfied, it may be determined that the first metal layer has excellent characteristics in terms of melting point, plating efficiency, and presence of voids in a range of 4 μm or less (including absence).

Table 2 below shows the roughness (L value) and color uniformity according to the third metal layer in the core ball. There is no specific unit for the roughness (L value), and when the roughness (L value) is in a range of 71 to 75, the roughness properties may be determined to be excellent.

The roughness (L value) may be measured before and after shaking, and thus a roughness value before shaking and a roughness value after shaking may slightly differ from each other, but generally, there may not be a big difference.

TABLE 2

| | | | | | | | | | | Roughness | | |
|---|---|---|---|---|---|---|---|---|---|---|---|---|
| | | | | | | | Second | Third | | (L Value) | | |
| | | | | | | | Metal | Metal | | Before | After | Color |
| | Sn—Bi | Sn | Ag | Cu | Stabilizer | Additive | Layer | Layer | Plating Composition | Shaking | Shaking | Uniformity |
| Example 6 | ◯ | X | X | X | 3 ml/L | 0.05 ml/L | ◯ | X | Sn-50~65Bi | 68 | 65 | Non-uniform |
| Example 8 | ◯ | ◯ | X | X | | | | ◯ | Sn-50~65Bi | 73 | 72 | Uniform |
| Example 9 | ◯ | ◯ | ◯ | ◯ | | | | ◯ | Sn-45~60Bi—0.3Ag—0.05Cu | 74 | 73 | Uniform |
| Example 10 | ◯ | ◯ | ◯ | ◯ | | | | ◯ | Sn-45~60Bi—0.5Ag—0.09Cu | 74 | 73 | Uniform |
| Example 11 | ◯ | ◯ | ◯ | ◯ | | | | ◯ | Sn-45~60Bi—1.0Ag—0.20Cu | 74 | 73 | Uniform |
| Example 12 | ◯ | ◯ | X | ◯ | | | | ◯ | Sn-45~60Bi—0.5Cu | 74 | 73 | Uniform |
| Example 13 | ◯ | ◯ | ◯ | X | | | | ◯ | Sn-45~60Bi—1.0Ag | 74 | 73 | Uniform |

Referring to FIGS. 9A, 9B, and 9C and Table 2 together, experiment results of improving physical properties of a plating composition according to the third metal layer in the core ball is shown.

Examples 6 and 8 to 11 show results according to the presence of the third metal layer after plating the Sn—Bi binary alloy that is the second metal layer.

For example, when only the Sn—Bi binary alloy is plated as in Example 6, due to rapid oxidation properties of Bi, a roughness value is in a level of 68 on the outer surface of the core ball, which is relatively dark. Furthermore, it appears that when the core ball is mounted on a semiconductor substrate, due to discoloration, a pickup error rate increases in pickup equipment.

Unlike the above, even when the core ball according to an embodiment is plated with only Sn as the third metal layer, as in Example 7, it may be confirmed that color uniformity is improved and the roughness value is improved, as the result of Example 8.

In some embodiments, the surface of each of Examples 6, 8, and 10 was observed microscopically as shown in the drawings, and it may be identified that as shown in the image of Example 6, Bi was relatively exposed much on the outer surface of the core ball so as to cause relatively rapid oxidation. Unlike the above, in the images of Examples 8 and 10, as no Bi exists on the outer surface of the core ball, it may be confirmed that a relatively smooth shape is observed through a microscope.

According to such experiment results, on the outer surface of the core ball according to an embodiment, due to the structural characteristics of containing no Bi, a core ball with resistance to discoloration (i.e., not easily discolored) was obtained.

In other words, by using the role of the third metal layer 17 (see FIG. 1) included in the core ball 10 (see FIG. 1), the core ball 10 (see FIG. 1) that is a high-quality, low-melting-point solder alloy according to the disclosure, which may improve physical properties of a plating composition, restrict oxidation of an outer surface, and exhibit void-free level bonding properties, may be manufactured.

FIG. 10 illustrates a semiconductor package including a core ball according to an embodiment.

Referring to FIG. 10, a substrate 110, on which a plurality of first terminals 112 are formed, is provided. The substrate 110 may be, for example, a printed circuit board (PCB) or a flexible printed circuit board (FPCB).

In some embodiments, the first terminals 112 may be organic solderability preservative (OSP) copper (Cu-OSP) pads.

In some embodiments, the first terminals 112 may be bonding pads each having an electroplated nickel layer. The bonding pad having an electroplated nickel layer may be a bonding pad obtained by forming an electroplated nickel layer on a copper pad by electroplating and forming an Au layer on the electroplated nickel layer.

In some embodiments, the first terminals 112 may be bonding pads each having an electroless nickel layer. The bonding pad having an electroless nickel layer may be, for example, a pad such as an electroless nickel-immersion gold (ENIG), an electroless nickel-electroless palladium-immersion gold (ENEPIG), etc.

The first terminals 112 may be bonding pads on which solder bumps are combined, and may have a structure of a single metal layer or in which a plurality of metals are stacked. Furthermore, the first terminals 112 may each include Cu, Al, Ni, or an alloy of two types or more thereof, but the disclosure is not limited thereto.

A semiconductor device 120 having a plurality of second terminals 122 corresponding to the first terminals 112 may be mounted on the substrate 110. The semiconductor device 120 may each be, for example, flash memory, phase-change RAM, (PRAM), resistive RAM (RRAM), ferroelectric RAM (FeRAM), magnetic RAM (MRAM), etc., but the disclosure is not limited thereto. The flash memory may be, for example, NAND flash memory. The semiconductor device 120 may be formed in one semiconductor chip or may be formed in a structure in which a plurality of semiconductor chips are stacked. Furthermore, the semiconductor device 120 may be one semiconductor chip or a semiconductor package in which a semiconductor chip is mounted on a package substrate and the semiconductor chip is encapsulated by an encapsulation material.

The first terminals 112 and the second terminals 122 that respectively correspond thereto may be connected to each other by a plurality of solder bumps 130. The solder bumps 130 may each include the core ball 10 having the composition as described above.

In some embodiments, the solder bumps 130, as described above, may include the core ball 10 that includes the core 11 that is metal or plastic, the first metal layer 13 formed on the surface of the core 11, the second metal layer 15 formed on the first metal layer 13 and including a Sn—Bi binary alloy, and the third metal layer 17 formed on the second metal layer 15 and including a single metal of Sn, wherein the melting point of an alloyed material of the second metal layer 15 and the third metal layer 17 is 150° C. or less.

As such, when the substrate 110 is connected to the semiconductor device 120 by using the solder bumps 130, warpage of a semiconductor package may be addressed through a low temperature process so that a high-quality result may be obtained, and thus, the semiconductor package 100 with excellent properties of both electrical and mechanical properties may be obtained.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the disclosure as defined by the following claims.

What is claimed is:

1. A core ball comprising:
a core that is metal or plastic;
a first metal layer formed on a surface of the core;
a second metal layer formed on the first metal layer and including a tin (Sn)—bismuth (Bi) binary alloy; and
a third metal layer formed on the second metal layer and including a single metal of tin (Sn),
wherein a melting point of an alloy of a material forming the second metal layer and a material forming the third metal layer is 150° C. or less.

2. The core ball of claim 1, wherein a diameter of the core is 50 μm to 800 μm,
a thickness of the first metal layer is 0.1 μm to 4 μm, and
the first metal layer further includes nickel (Ni).

3. The core ball of claim 1, wherein Bi is uniformly distributed in the second metal layer by a stabilizer for Bi, and
Bi is not detected from the third metal layer.

4. A core ball comprising:
a core that is metal or plastic;
a first metal layer formed on a surface of the core;
a second metal layer formed on the first metal layer and including any one alloy selected from among tin (Sn)—bismuth (Bi), tin (Sn)—indium (In), bismuth (Bi)—indium (In), tin (Sn)—bismuth (Bi)—silver (Ag), and tin (Sn)—bismuth (Bi)—antimony (Sb); and
a third metal layer formed on the second metal layer and including an alloy of tin (Sn) and at least one selected from silver (Ag) and copper (Cu),
wherein a melting point of an alloy of a material forming the second metal layer and a material forming the third metal layer is 150° C. or less, and
the third metal layer includes 80 wt % or more of tin (Sn).

5. The core ball of claim 4, wherein the core ball comprises:
a Bi content of 30 wt % to 70 wt %;
an Ag content of 0.01 wt % to 2.0 wt %;
a Cu content of 0.01 wt % to 0.8 wt %; and
the balance of Sn and other inevitable impurities.

6. The core ball of claim 5, wherein a melting point of an alloy of a material forming the second metal layer and a material forming the third metal layer is 138° C.

7. A semiconductor package comprising:
a substrate on which a plurality of first terminals are formed;
a semiconductor device mounted on the substrate and including a plurality of second terminals corresponding to the plurality of first terminals; and
a plurality of solder bumps connecting the plurality of first terminals to the plurality of second terminals, which correspond to each other,
wherein the plurality of solder bumps each comprise the core ball according to any one of claims 1 to 6.
